(19) United States
(12) Patent Application Publication
(10) Pub. No.: US 2016/0104814 A1
(43) Pub. Date: Apr. 14, 2016

(54) VERTICAL-TYPE SEMICONDUCTOR LIGHT-EMMITTING DEVICE AND METHOD OF FABRICATING THE VERTICAL-TYPE LIGHT-EMITTING DEVICE

(71) Applicant: Samsung Electronics Co., Ltd., Suwon-si (KR)

(72) Inventors: Junsik HWANG, Hwaseong-si (KR); Suhee CHAE, Suwon-si (KR)

(21) Appl. No.: 14/673,988

(22) Filed: Mar. 31, 2015

(30) Foreign Application Priority Data
Oct. 14, 2014 (KR) 10-2014-0138618

(51) Int. Cl. H01L 33/22; H01L 33/38; H01L 33/32; H01L 33/62; H01L 33/06; H01L 33/40; H01L 33/12

(52) U.S. Cl. CPC H01L 33/22; H01L 33/405; H01L 33/382; H01L 33/12; H01L 33/62; H01L 33/06; H01L 33/32

(57) ABSTRACT

A semiconductor light-emitting device includes an active layer and a first semiconductor layer sequentially stacked on a second semiconductor layer and including a plurality of contact holes exposing portions of the first semiconductor layer, a plurality of first electrodes on the exposed portions of the first semiconductor layer, a second electrode on the second semiconductor layer adjacent to the contact holes, a first insulating layer on the second electrode in the first region defining at least a portion of the contact holes and insulating the plurality of first electrodes from the active layer and the second semiconductor layer, a first bonding layer on the first insulating layer, filling the contact holes and connected to the first electrodes, a second bonding layer on the second electrode, and a conductive layer including first and second portions contacting a lower surface of the first bonding layer and the second bonding layer, respectively.

### CROSS REFERENCE TO RELATED APPLICATION

This application claims the benefit of Korean Patent Application No. 10-2014-0138618, filed on Oct. 14, 2014, in the Korean Intellectual Property Office, the disclosure of which is incorporated herein in its entirety by reference.

### BACKGROUND

1. Field

Some example embodiments relate to vertical-type semiconductor light-emitting devices in which current is applied from a lower surface thereof without using a through-silicon via (TSV) substrate.

2. Description of the Related Art

Light-emitting devices that use a semiconductor material, such as a Group III-V nitride semiconductor, have advantages that they have a relatively long lifetime and may be miniaturized and manufacture light. Currently, various techniques have been developed to increase the efficiency of these light-emitting devices. Recently, relatively high output and relatively high brightness light-emitting devices have drawn attention to use the light-emitting devices as general illumination devices. However, due to the characteristics of a light-emitting device, when relatively high power is applied to the light-emitting device to obtain a relatively high output, the efficiency of the light-emitting device is reduced as compared to a case when relatively low power is applied to the light-emitting device.

A vertical-type semiconductor light-emitting device having an efficient current application structure has been proposed. Unlike a horizontal-type light-emitting device in which a portion of a semiconductor layer is etched and an electrode is formed on the etched portion of the semiconductor layer, electrodes are directly located on a top surface and a bottom surface of a semiconductor layer in the vertical-type semiconductor light-emitting device, and thus, efficient current application from the electrodes to the semiconductor layer is possible. Accordingly, the vertical-type semiconductor light-emitting device may provide improved efficiency and output as compared to a horizontal-type light-emitting device.

In the vertical-type semiconductor light-emitting device, electrodes for applying a current may be located on a bottom surface of the vertical-type semiconductor light-emitting device by using a TSV substrate. However, the use of the TSV substrate increases manufacturing costs.

### SUMMARY

Some example embodiments provide vertical-type semiconductor light-emitting devices in which a current supply region is confined by forming a trench in a conductive substrate.

Other example embodiments provide methods of manufacturing the vertical-type semiconductor light-emitting devices. Additional aspects will be set forth in part in the description which follows and, in part, will be apparent from the description, or may be learned by practice of example embodiments.

According to an example embodiment, a semiconductor light-emitting device includes an active layer and a first semiconductor layer sequentially stacked on a second semiconductor layer, the active layer and the second semiconductor layer including a plurality of contact holes exposing portions of the first semiconductor layer in a first region of the second semiconductor layer; a plurality of first electrodes on respective ones of the exposed portions of the first semiconductor layer; a second electrode on the second semiconductor layer and adjacent to the plurality contact holes; a first insulating layer on the second electrode in the first region defining at least a portion of the contact holes and configured to insulate the plurality of first electrodes from the active layer and the second semiconductor layer; a first bonding layer on the first insulating layer and filling the plurality of contact holes, the first bonding layer connected to the plurality of first electrodes, a second bonding layer on the second electrode; and a conductive layer including a first portion contacting a lower surface of the first bonding layer and a second portion contacting a lower surface of the second bonding layer.

The semiconductor light-emitting device may further include a buffer layer on the first semiconductor layer, the buffer layer having a corrugated surface.

The second portion of the conductive layer may surround the first portion.

The second electrode may be a reflective layer configured to reflect light emitted from the active layer.

The first and second bonding layers may include one of AuSn, NiSn, CuSn and AgSn.

The semiconductor light-emitting device may further include a second insulating layer filling a trench between the first portion and the second portion of the conductive layer.

The trench may have a width in a range from about 1 μm about 10 μm.

The conductive layer may be a silicon substrate.

The semiconductor light-emitting device may further include a first electrode pad connected to a lower surface of the first portion, and a second electrode pad connected to a lower surface of the second portion.

According to another example embodiment, a semiconductor light-emitting device includes an active layer and a first semiconductor layer sequentially stacked on a second semiconductor layer, the active layer and the second semiconductor layer including a plurality of contact holes exposing portions of the first semiconductor layer in a first region of the second semiconductor layer; a plurality of first electrodes on respective ones of the exposed portions of the first semiconductor layer; a second electrode on the second semiconductor layer and adjacent to the plurality of contact holes; a first insulating layer on the second electrode in the first region defining at least a portion of the plurality of contact holes and configured to insulate the plurality of first electrodes from the active layer and the second semiconductor layer; a first bonding layer on the first insulating layer and filling the plurality of contact holes, the first bonding layer connected to the plurality of first electrodes; a second bonding layer on the second electrode; a conductive layer including a first portion connected to the first bonding layer and surrounded by a first trench, and a second portion connected to the second bonding layer and surrounded by a second trench; and a second insulating layer covering an upper surface of the conductive layer to surround the first trench and the second trench, the second insulating layer filling the first trench and the second trench.

The first and second portions may be formed of the same material.

The semiconductor light-emitting device may further include a buffer layer on the first semiconductor layer, the buffer layer having a corrugated surface.

The first and second trenches may have a width in a range from about 1 μm to about 10 μm.

The second electrode may be a reflective layer configured to reflect light emitted from the active layer.

The first and second bonding layers may include one of AuSn, NiSn, CuSn, and AgSn.

The conductive layer may be a silicon layer.

The semiconductor light-emitting device may further include a first electrode pad connected to a lower surface of the first portion, and a second electrode pad connected to a lower surface of the second portion.

According to another example embodiment, a method of manufacturing a semiconductor light-emitting device includes manufacturing a semiconductor structure including sequentially forming a first semiconductor layer, an active layer and a second semiconductor layer on a first substrate in order, the second semiconductor layer including a first region and a second region surrounding the first region, etching the second semiconductor layer and the active layer to form a plurality of contact holes exposing portions of the first semiconductor layer, forming a second electrode on the second semiconductor layer adjacent to the plurality of contact holes, forming a first insulating layer on the second electrode and defining at least a portion of the plurality of contact holes, forming a plurality of first electrodes on respective ones of the exposed portions of the first semiconductor layer, removing the first insulating layer adjacent to the plurality of contact holes in the second region, forming a first bonding layer covering the first region and connected to the plurality of first electrodes, and forming a second bonding layer covering the second electrode in the second region; manufacturing an electrode structure including patterning a conductive substrate to form a trench separating the first region and second region, forming a second insulating layer in the trench, and forming a third bonding layer on an upper surface of the conductive substrate corresponding with the first bonding layer and a fourth bonding layer on the upper surface corresponding with the second bonding layer, bonding the semiconductor structure and the electrode structure by bonding the first and second bonding layers to the third and fourth bonding layers, respectively; exposing the second insulating layer by polishing a lower surface of the conductive substrate; and removing the first substrate.

The bonding may be eutectic bonding, and the first, second, third and fourth bonding layers include one of AuSn, NiSn, CuSn and AgSn.

The method may further include forming a buffer layer between the first substrate and the first semiconductor layer, wherein the removing the first substrate includes processing a surface of the buffer layer such that the surface is corrugated.

The trench may have a width in a range from about 1 μm to about 10 μm.

The conductive substrate may be a silicon substrate.

Exposing the second insulating layer may further include forming a first electrode pad on a lower surface of the conductive substrate corresponding with the first region, and forming a second electrode pad on the lower surface of the conductive substrate corresponding with the second region.

According to another example embodiment, a method of manufacturing a semiconductor light-emitting device includes manufacturing a semiconductor structure including sequentially forming a first semiconductor layer, an active layer, and a second semiconductor layer on a first substrate in order, etching the second semiconductor layer and the active layer to form a plurality of contact holes exposing portions of the first semiconductor layer, forming a second electrode on the second semiconductor layer adjacent to the plurality of contact holes, forming a first insulating layer on the second electrode and defining at least a portion of the plurality of contact holes, forming a plurality of first electrodes on respective ones of the exposed portions of the first semiconductor layer, removing the first insulating layer adjacent to the plurality of contact holes in the second region, forming a first bonding layer covering the first region and connected to the plurality of first electrodes, and forming a second bonding layer covering the second electrode in the second region; manufacturing an electrode structure including patterning a conductive substrate to form first and second trenches corresponding with the first bonding layer and the second bonding layer, respectively, forming a second insulating layer on the conductive substrate and filling the first and second trenches, removing a portion of the second insulating layer above the first and second trenches, and forming a third bonding layer on the second insulating layer corresponding with the first bonding layer and a fourth bonding layer on the second insulating layer corresponding with the second bonding layer, bonding the semiconductor structure to the electrode structure by bonding the first and second bonding layers to the third and fourth bonding layers, respectively; exposing the second insulating layer by polishing a lower surface of the conductive substrate; and removing the first substrate.

The bonding may be eutectic bonding, and the first, second, third and fourth bonding layers include one of AuSn, NiSn, CuSn and AgSn.

The method may further include forming a buffer layer between the first substrate and the first semiconductor layer, wherein the removing the first substrate includes processing a surface of the buffer layer such that the surface is corrugated.

The trench may have a width in a range from about 1 μm to about 10 μm.

The conductive substrate may be a silicon substrate.

Exposing the second insulating layer may further include forming a first electrode pad on a lower surface of the conductive substrate corresponding with the third bonding layer, and forming a second electrode pad on the lower surface of the conductive substrate corresponding with the fourth bonding layer.

Each of the first and second trenches may have one of a circular shape and a rectangular shape when viewed from a plan view.

### BRIEF DESCRIPTION OF THE DRAWINGS

These and/or other aspects will become apparent and more readily appreciated from the following description of the example embodiments, taken in conjunction with the accompanying drawings in which:

FIG. 1 is a schematic cross-sectional view of a structure of a vertical-type semiconductor light-emitting device according to an example embodiment;

FIG. 2 is a plan view taken along line II-II of FIG. 1;

FIGS. 3A through 3E are cross-sectional views for explaining a method of preparing a semiconductor structure of the vertical-type semiconductor light-emitting device of FIG. 1;

FIGS. 4A through 4C are cross-sectional views for illustrating a method of preparing an electrode structure of the vertical-type semiconductor light-emitting device of FIG. 1;

FIGS. 5A through 5E are cross-sectional views for illustrating a method of manufacturing the vertical-type semiconductor light-emitting device by combining the semiconductor structure of FIG. 3 and the electrode structure of FIG. 4;

FIG. 6 is a schematic cross-sectional view of a structure of a vertical-type semiconductor light-emitting device according to another example embodiment;

FIG. 7 is a plan view taken along line VII-VII of FIG. 6; and

FIGS. 8A through 8D are cross-sectional views for illustrating a method of preparing an electrode structure of the vertical-type semiconductor light-emitting device of FIG. 6.

### DETAILED DESCRIPTION

Reference will now be made in detail to example embodiments, examples of which are illustrated in the accompanying drawings. In the drawings, the thicknesses of layers and regions are exaggerated for clarity. The example embodiments of the inventive concepts are capable of various modifications and may be embodied in many different forms. It will be understood that when an element or layer is referred to as being “on” another element or layer, the element or layer may be directly on another element or layer or intervening elements or layers. Like reference numerals in the drawings denote like elements throughout the specification, and thus their description will be omitted.

It will be understood that when an element or layer is referred to as being “on,” “connected to,” “coupled to,” or “covering” another element or layer, it may be directly on, connected to, coupled to, or covering the other element or layer, or intervening elements or layers may be present. In contrast, when an element is referred to as being “directly on,” “directly connected to,” or “directly coupled to” another element or layer, there are no intervening elements or layers present. Like numbers refer to like elements throughout the specification. As used herein, the term “and/or” includes any and all combinations of one or more of the associated listed items.

It will be understood that, although the terms first, second, third, etc. may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of the example embodiments.

Spatially relative terms, e.g., “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” may encompass both an orientation of above and below. The device may be otherwise oriented (rotated 90 degrees or at other orientations) and the spatially relative descriptors used herein interpreted accordingly.

The terminology used herein is for the purpose of describing various embodiments only and is not intended to be limiting of the example embodiments. As used herein, the singular forms “a,” “an,” and “the” are intended to include the plural forms as well, unless the context clearly indicates otherwise. It will be further understood that the terms “comprises,” “comprising,” “includes,” and/or “including,” if used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art. It will be further understood that terms, including those defined in commonly used dictionaries, should be interpreted as having a meaning that is consistent with their meaning in the context of the relevant art and will not be interpreted in an idealized or overly formal sense unless expressly so defined herein.

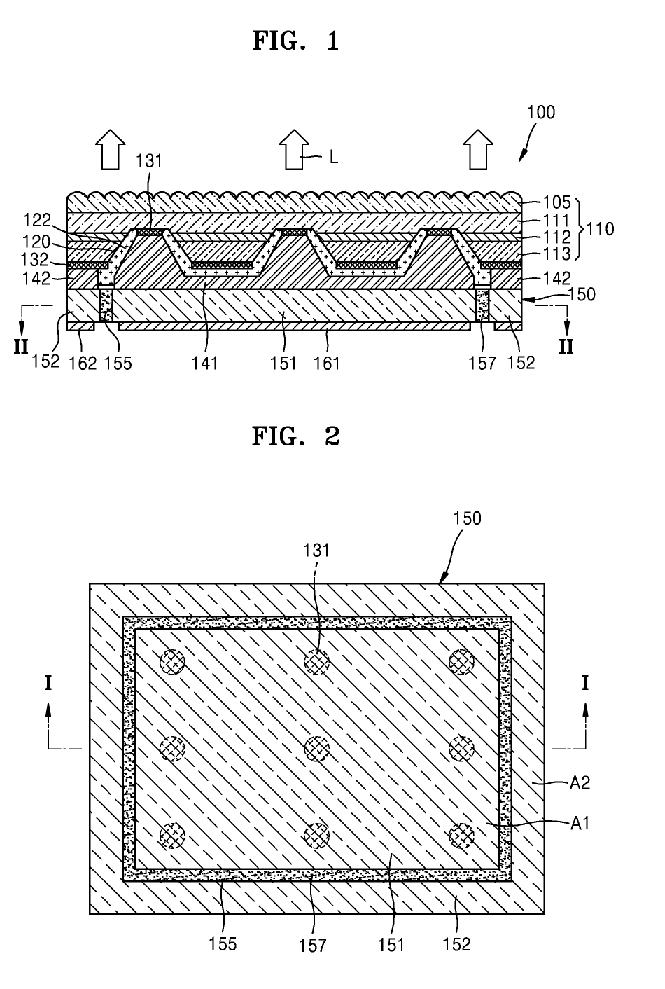

FIG. 1 is a schematic cross-sectional view of a structure of a vertical-type semiconductor light-emitting device 100 according to an example embodiment. FIG. 2 is a plan view taken along line II-II of FIG. 1.

Referring to FIGS. 1 and 2, the vertical-type semiconductor light-emitting device 100 includes a semiconductor structure 110 and an electrode structure formed on one surface of the semiconductor structure 110.

The semiconductor structure 110 includes a first semiconductor layer 111, an active layer 112, and a second semiconductor layer 113 that are sequentially formed by crystal growth on a buffer layer 105. A surface of the buffer layer 105 may be corrugated. The corrugated surface may increase the optical extraction efficiency of the vertical-type semiconductor light-emitting device 100.

In a process of forming the semiconductor structure 110, when a sapphire substrate is used, the buffer layer 105 may be omitted. The sapphire substrate may be removed in a manufacturing process.

The semiconductor structure 110 is formed of a Group III-V semiconductor, for example, GaN, InN, AlN, etc. The sapphire substrate may be used for crystal growth since the sapphire substrate has a similar lattice structure to that of nitride semiconductor structures. The first semiconductor layer 111 may have n-type conductivity, and the second semiconductor layer 113 may have p-type conductivity. The first semiconductor layer 111 may have p-type conductivity, and the second semiconductor layer 113 may have n-type conductivity.

The active layer 112 is disposed between the first semiconductor layer 111 and the second semiconductor layer 113, for example, as a multi-quantum well structure. The multi-quantum well structure includes a plurality of quantum well layers and a plurality of quantum barrier layers formed between the quantum well layers. As a practical example, if the semiconductor structure 110 is a GaN-based light-emitting device, the first semiconductor layer 111 may be formed of GaN doped with an n-type impurity, the second semiconductor layer 113 may be formed of GaN doped with a p-type impurity, and the active layer 112 may be formed by alternately stacking multi-well layers formed of InGaN and quantum barrier layers formed of GaN. Electrons and holes injected through the first semiconductor layer 111 and the second semiconductor layer 113 are combined in the active layer 112 to emit light L. Emitted light L is discharged through the first semiconductor layer 111 of the semiconductor structure 110.

Contact holes 120 are formed through the second semiconductor layer 113 and the active layer 112 from a lower surface of the second semiconductor layer 113 to contact a portion of the first semiconductor layer 111. As depicted in FIG. 1, the contact holes 120 may pass through a certain region of the first semiconductor layer 111. First electrodes 131 are formed on bottom surfaces of the contact holes 120 or the exposed portion of the first semiconductor layer 111. The first electrodes 131 may rapidly supply current to the first semiconductor layer 111 by diffusing the current.

The contact holes 120 may be arranged in a matrix form in consideration of current diffusion and optical extraction. As depicted in FIG. 2, the matrix arrangement may have an equal distance in at least one of a horizontal direction or a vertical direction. Accordingly, if necessary, the arrangement of the contact holes 120 may be a random distribution having different distances therebetween.

The contact holes 120 may have a size (diameter) in a range from about 30 μm to about 100 μm.

A first insulating layer 122 that surrounds the first electrode 131 is formed in each of the contact holes 120. The first insulating layer 122 electrically insulates the first electrode 131 from other layers except the first semiconductor layer 111.

A second electrode 132 is formed on the second semiconductor layer 113, except for the region of the contact holes 120. The second electrode 132 may be formed to be adjacent to or surround the contact holes 120. Since the second electrode 132 is electrically connected to the second semiconductor layer 113, the second electrode 132 may be formed of a material that minimizes or reduces a contact resistance with the second semiconductor layer 113 and increases light emission efficiency by reflecting light generated from the active layer 112 to the external environment. For example, the second electrode 132 may include, for example, Ag, Al, Pt, Ni, Pd, Ti, Au, Ir, W, Sn, an oxide of these materials, or a mixture of these materials. The second electrode 132 may be formed as a single layer or a plurality of layers. The first insulating layer 122 may be formed to cover the second electrode 132 between the contact holes 120.

A first bonding layer 141 is formed on the first insulating layer 122, and a second bonding layer 142 is formed on an exposed portion of the second electrode 132 which is exposed by the first insulating layer 122. The second bonding layer 142 may be formed to surround the first bonding layer 141. The first bonding layer 141 may be formed separate from the second bonding layer 142.

A silicon substrate 150, for example, a low-resistance silicon substrate, is formed under the first and second bonding layers 141 and 142. The silicon substrate 150, for example, a low-resistance silicon substrate, includes a first portion 151 and a second portion 152 that respectively correspond to the first bonding layer 141 and the second bonding layer 142. A trench 155 is formed between the first and second portions 151 and 152, and a second insulating layer 157 is formed to fill the trench 155.

Another conductive substrate may be used instead of the silicon substrate 150, for example, a low-resistance silicon substrate. For example, the conductive substrate may be formed of a Ge group material, an Si group material that includes aluminum, a nitride group material such as GaN.

A first electrode pad 161 and a second electrode pad 162 may be formed on a bottom surface of the silicon substrate 150, for example, a low-resistance silicon substrate. The first electrode pad 161 is formed to be connected to the first portion 151, and the second electrode pad 162 is formed to be connected to the second portion 152.

As described above, in the vertical-type semiconductor light-emitting device 100 according to the example embodiment, electrodes are formed to reduce loss of a light emission area by forming the electrodes connected to the first and second semiconductor layers 111 and 113 on a bottom surface of the vertical-type semiconductor light-emitting device 100, and thus, the light emission efficiency of the light-emitting device 100 may be maximized.

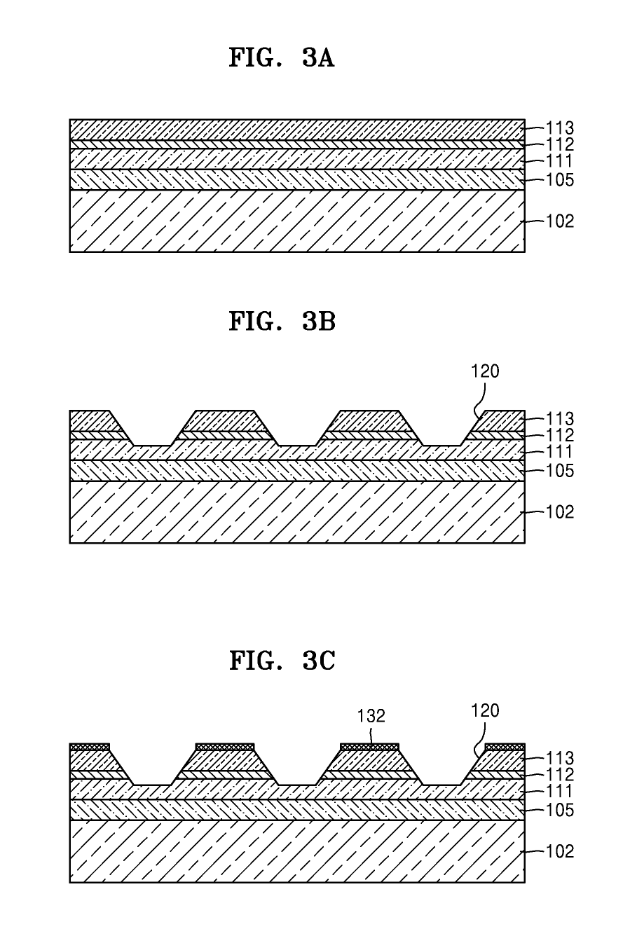

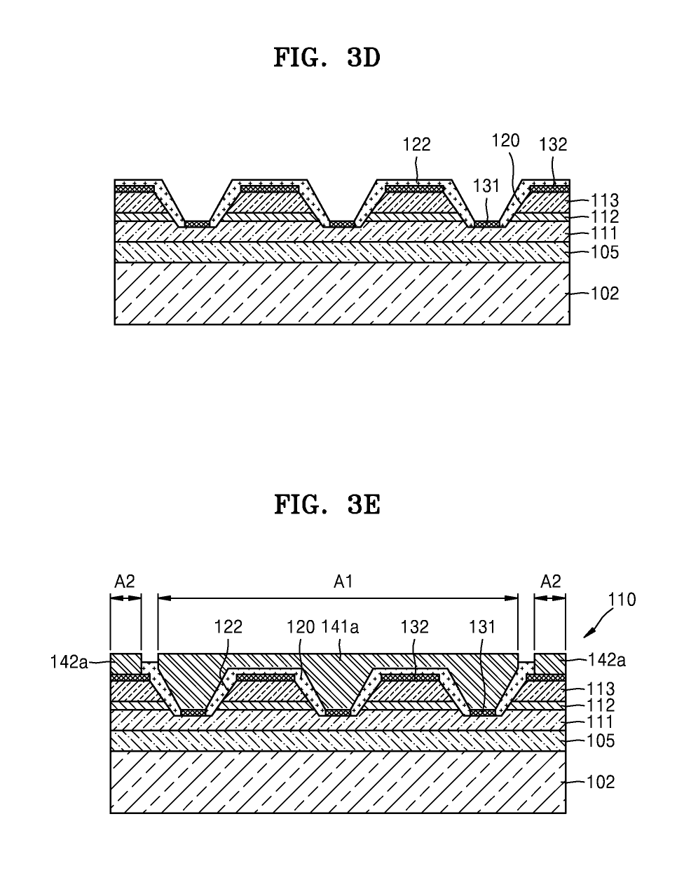

A method of manufacturing the vertical-type semiconductor light-emitting device 100 of FIG. 1 will be described. FIGS. 3A through 3E are cross-sectional views for illustrating a method of preparing a semiconductor structure of the vertical-type semiconductor light-emitting device 100 of FIG. 1. Like reference numerals are used to indicate elements that are substantially identical to the elements of FIG. 1 and the detailed descriptions thereof will not be repeated. In FIGS. 3A through 3E, for convenience of description, a method of manufacturing a single vertical-type semiconductor light-emitting device 100 is described. However, after forming a plurality of vertical-type semiconductor light-emitting devices on a wafer, individual vertical-type semiconductor light-emitting devices may be formed by dicing the wafer, or a light-emitting device having a plurality of vertical-type semiconductor light-emitting devices as one body may be fabricated.

Referring to FIG. 3A, after forming a buffer layer 105 on a substrate 102, the semiconductor structure 110 is formed by sequentially forming the first semiconductor layer 111, the active layer 112, and the second semiconductor layer 113 on the buffer layer 105 in this order by a crystal growth. The substrate 102 may be formed of a material that is appropriate for forming a semiconductor by a crystal growth. For example, in the case of growing a nitride semiconductor single crystal, the substrate 102 may be a sapphire substrate, a ZnO substrate, a GaN substrate, a SiC substrate, or an AlN substrate. In this case, the buffer layer 105 may be omitted.

The substrate 102 may have a thickness in a range from about 300 μm to about 1,200 μm according to the size thereof. The buffer layer 105 is a layer for improving lattice matching between the grown first semiconductor layer 111 and the substrate 102. For example, in the case of growing a nitride semiconductor single crystal, the buffer layer 105 may include one of SiC, nitride (GaN, AlGaN, InGaN, InN, AlInGaN, AlN, etc.), Zn oxide, and Si oxide, or a combination of these materials.

A single crystal semiconductor layer is formed on the buffer layer 105. The semiconductor structure 110 may be formed by crystal growth, for example, a Group III-V semiconductor, such as GaN, InN, and AlN. As an example, if the semiconductor structure 110 is a GaN-based light-emitting diode, the first semiconductor layer 111, the active layer 112, and the second semiconductor layer 113 may be a semiconductor material having a chemical formula of AlₓIn_{y}Ga(_{1-x-y})N (here, 0≦x≦1, 0≦y≦1, and 0≦x+y≦1), and may be formed by using an epitaxial growth method using a metal organic chemical vapor deposition (MOCVD) apparatus. The first semiconductor layer 111 may be a nitride semiconductor layer (GaN, InN, InGaN, AlGaN, AlN, AlInGaN, or a combination of these materials) that is doped with a first type impurity such as Si, Ge, or Sn, non-doped, or a combination of these materials.

The active layer 112 may be formed of a multi-quantum well structure (an InGaN/GaN layer, an InGaN/InGaN layer, an AlGaN/GaN layer, an AlGaN/AlGaN layer, an AlInGaN/AlInGaN layer, or a combination of these layers), or may be formed in a single-quantum well layer or a double heterostructure. The second semiconductor layer 113 may be a nitride semiconductor layer (GaN, InN, InGaN, AlGaN, AlN, AlInGaN, or a combination of these materials) that is doped with a first type impurity such as Mg, Zn, or Be, non-doped, or a combination of these materials. The first semiconductor layer 111, the active layer 112, and the second semiconductor layer 113 may have various thicknesses (in a range from 1 nm to 10,000 nm) or various impurity concentrations (in a range from 1×10¹⁵/cm³ to 1×10²²/cm³) according to the role of corresponding layers.

Referring to FIG. 3B, contact holes 120 are formed by dry etching (an inductively coupled etching-reactive ion etching (ICE-RIE) method) and/or wet etching to a given (or alternatively, predetermined) depth (in a range from 0.5 μm to 20 μm) from the second semiconductor layer 113 to a certain depth in the first semiconductor layer 111. Portions of the second semiconductor layer 113 and the active layer 112 are removed until a surface of the first semiconductor layer 111 is exposed. The first semiconductor layer 111 may also be etched to a certain depth (in a range from 0.1 nm to 5,000 nm), and if necessary, through holes may be formed. The contact holes 120 may have a size (diameter) in a range from about 5 μm to about 300 μm. The contact holes 120 may be formed in plural numbers.

Referring to FIG. 3C, a second electrode 132 that surrounds or is adjacent to the contact holes 120 is formed on the second semiconductor layer 113. The second electrode 132 may be formed by using a lift-off process or an etching process.

The second electrode 132 may be formed as a reflection film by forming a metal that has both an ohmic characteristic and an optical reflection characteristic, or by forming a multi-layer structure in which a metal having an ohmic characteristic and a metal having an optical reflection characteristic are stacked. The second electrode 132 may be formed by including at least one of Ag, Al, Pt, Ni, Pd, Ti, Au, Ir, W, Sn, an oxide of these materials, or a mixture of these materials as a single layer or multi-layers. These material increases extraction of light to the outside.

Referring to FIG. 3D, a first insulating layer 122 is formed on a whole upper region of the semiconductor structure 110 by using a deposition method. For example, the first insulating layer 122 may be formed by depositing SiO₂ or SiNₓ using Plasma-Enhanced Chemical Vapor Deposition (PECVD).

The first semiconductor layer 111 is exposed by etching the first insulating layer 122 on the bottom of or in the contact holes 120. Here, a portion of the first semiconductor layer 111 may be etched together. The etching may be, for example, a dry etching of reactive ion etching (RIE) or a wet etching by using a buffered oxide etchant.

First electrodes 131 are formed on the exposed regions of the first semiconductor layer 111. The first electrodes 131 may be formed of a material that may form an ohmic contact with the first semiconductor layer 111 and has a high reflectance. For example, the first electrodes 131 may be formed of a material that includes at least one of Al, Ti, Pt, Ag, Ni, TiN, Au, Sn, or a mixture of these materials, as a single layer or multi-layers. For example, a Ti/Ni/Au layer is formed. At this point, as depicted in FIG. 2, the first electrodes 131 are formed in plural to increase a current spreading effect. The first electrodes 131 may be arranged in a matrix form. After forming the first electrodes 131, a thermal annealing may be performed to form an ohmic contact. The thermal annealing may be performed at a temperature in a range from about 300° C. to about 600° C. for a time in a range from about 30 seconds to about 180 seconds by using a rapid thermal annealing (RTA) method.

Referring to FIG. 3E, a portion of the second electrode 132 is exposed by patterning the first insulating layer 122. As shown in FIG. 2, the exposed portion of the second electrode 132 is formed to surround a region (a first region A1) surrounding the contact holes 120. The second electrode 132 is exposed in a second region A2. The first region A1 and the second region A2 are separately formed.

A first bonding layer 141a is formed on the first insulating layer 122 in the first region A1 and contacts the first electrodes 131. A second bonding layer 142a is formed on the second region A2 and contacts the second electrode 132. The first bonding layer 141 a and the second bonding layer 142a may be formed of an eutectic bonding material, for example, AuSn, NiSn, CuSn, AgSn, etc.

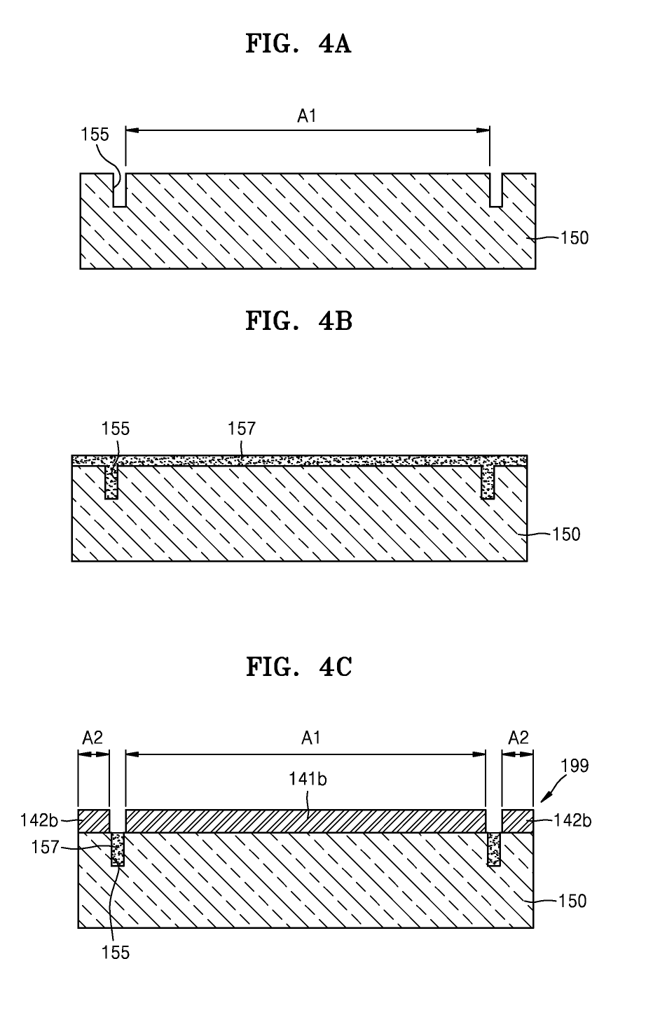

FIGS. 4A through 4C are cross-sectional views for illustrating a method of preparing an electrode structure of the vertical-type semiconductor light-emitting device 100 of FIG. 1.

Referring to FIG. 4A, a conductive substrate 150 is prepared. The conductive substrate 150 may be a silicon substrate, for example, a low-resistance silicon substrate. However, the example embodiment is not limited thereto. For example, the conductive substrate 150 may be formed of a Ge group material, a Si group material that includes aluminum, or a nitride group material (GaN etc.). Hereinafter, a method of manufacturing an electrode structure is described with the silicon substrate, for example, the low-resistance silicon substrate. The conductive substrate 150 may be referred to as the silicon substrate 150, for example, the low-resistance silicon substrate.

A trench 155 is formed in an upper surface of the silicon substrate 150, for example, the low-resistance silicon substrate. The trench 155 may be formed in a shape that defines the first region A1.

Referring to FIG. 4B, a second insulating layer 157 is formed on the upper surface of the silicon substrate 150, for example, the low-resistance silicon substrate, and covers the trench 155. The second insulating layer 157 may be formed of an oxide, a nitride, or a polymer. The second insulating layer 157 may be a silicon oxide layer formed by thermally oxidizing the silicon substrate 150, for example, a low-resistance silicon substrate. The trench 155 may have a depth in a range from about 100 μm to about 300 μm and a diameter in a range from about 1 μm to about 10 μm so that the trench 155 is completely filled with a silicon oxide layer.

Referring to FIG. 4C, the second insulating layer 157 in the first region A1, that is, inside the trench 155, and the second insulating layer 157 in the second region A2, that is, outside the trench 155, are removed by patterning the second insulating layer 157 on the upper surface of the silicon substrate 150, for example, a low-resistance silicon substrate. The second insulating layer 157 that fills the trench 155 remains.

A third bonding layer 141b and a fourth bonding layer 142b respectively are formed in the first region A1 and the second region A2 on the upper surface of the silicon substrate 150, for example, a low-resistance silicon substrate. For this process, a photoresist (not shown) may be formed in advance on the trench 155, and bonding material for the third bonding layer 141b and the fourth bonding layer 142b is formed on the silicon substrate 150, for example, the low-resistance silicon substrate, and the photoresist on the trench is removed with the bonding material thereon by using lift-off process. The third and fourth bonding layers 141b and 142b may be formed of an eutectic bonding material, for example, AuSn, NiSn, CuSn, AgSn, etc. Hereinafter, the resultant structure of FIG. 4C is referred to as an electrode structure 199.

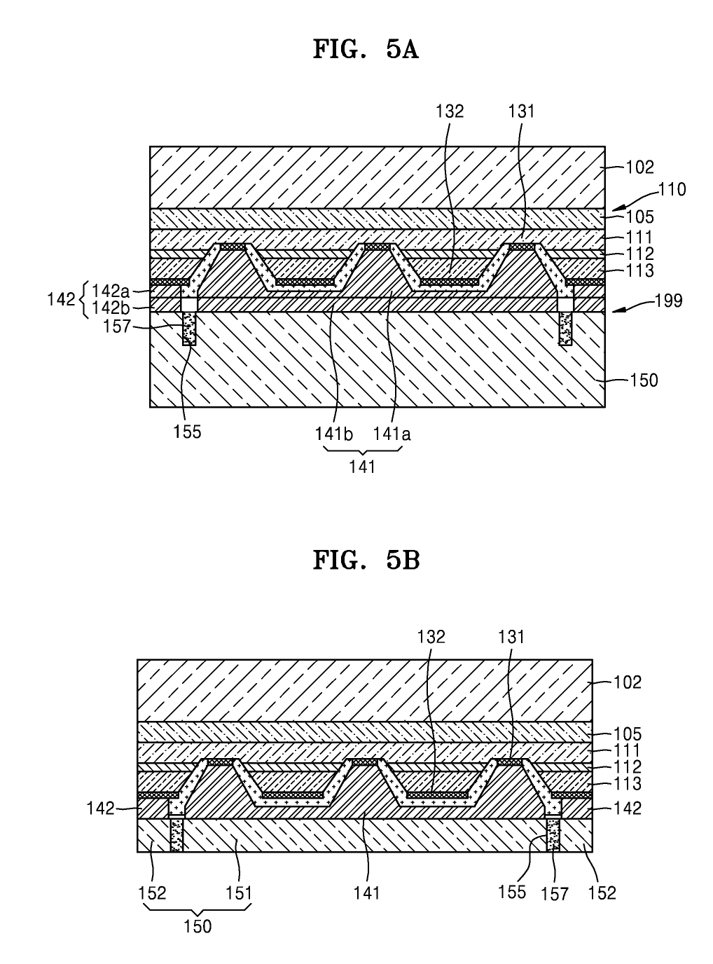

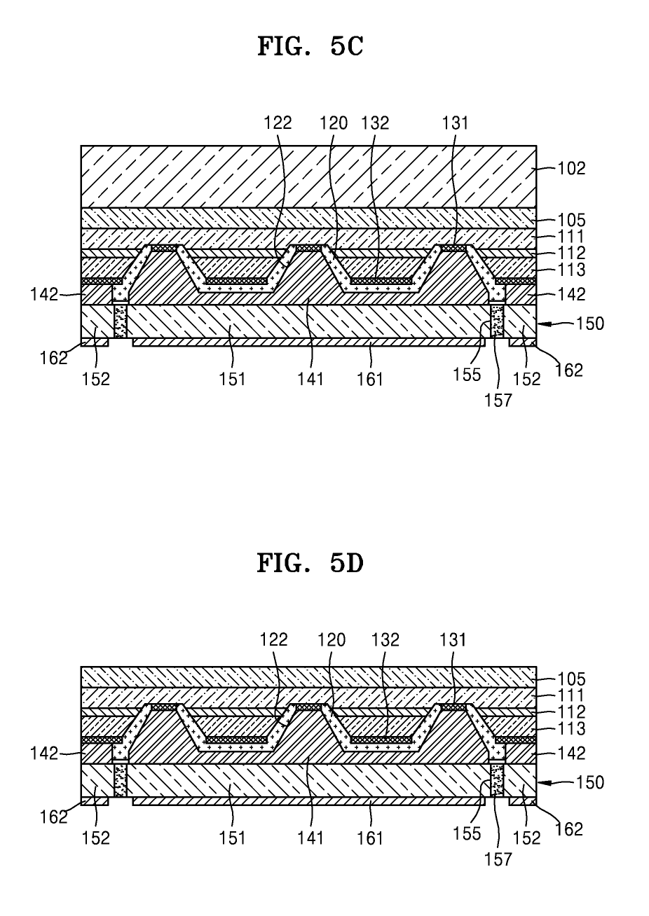

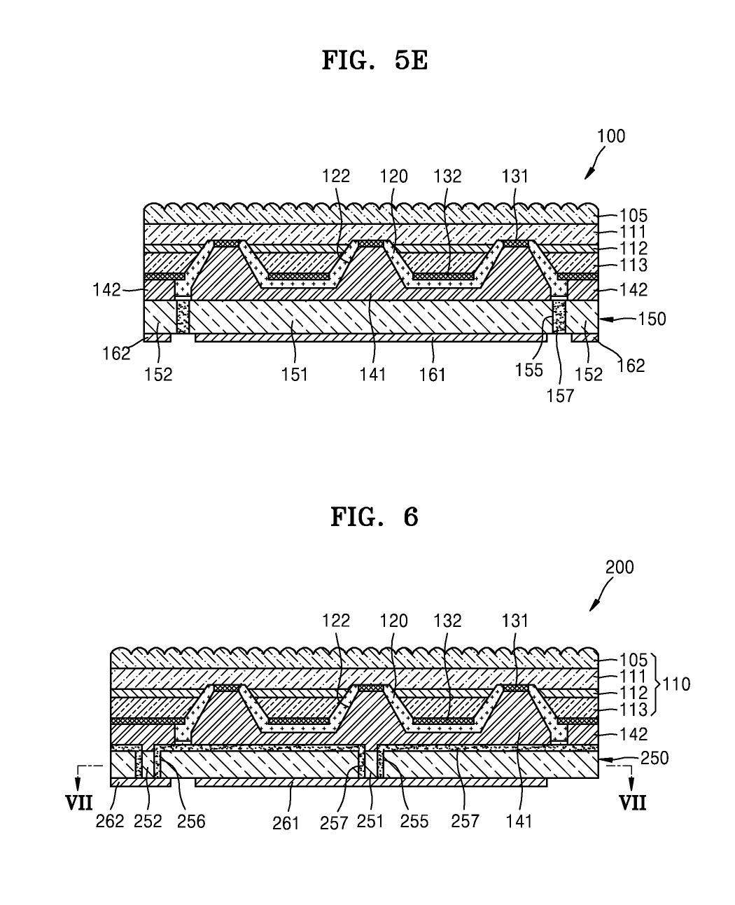

FIGS. 5A through 5E are cross-sectional views for illustrating a method of manufacturing the vertical-type semiconductor light-emitting device 100 of FIG. 1 by combining the semiconductor structure 110 and the electrode structure 199.

Referring to FIG. 5A, after disposing the first bonding layer 141a and the second bonding layer 142a of the semiconductor structure 110 to contact the third bonding layer 141b and the fourth bonding layer 142b of the electrode structure 199, the semiconductor structure 110 and the electrode structure 199 are bonded by using an eutectic bonding method. The first bonding layer 141a and the third bonding layer 141b become a fifth bonding layer 141 by bonding with each other, and the second bonding layer 142b and the fourth bonding layer 142b become a sixth bonding layer 142 by bonding with each other.

Referring to FIG. 5B, the second insulating layer 157 in the trench 155 is exposed by polishing a lower surface of the silicon substrate 150, for example, a low-resistance silicon substrate. The silicon substrate 150, for example, a low-resistance silicon substrate, includes a first portion 151 that corresponds to the fifth bonding layer 141 and a second portion 152 that corresponds to the sixth bonding layer 142. Hereinafter, the polished silicon substrate 150, for example, a low-resistance silicon substrate, may be referred to as a conductive layer.

Referring to FIG. 5C, a first electrode pad 161 and a second electrode pad 162 are respectively formed on lower surfaces of the first portion 151 and the second portion 152 of the silicon substrate 150, for example, a low-resistance silicon substrate. The first electrode pad 161 and the second electrode pad 162 may be formed by forming a metal on the lower surface of the silicon substrate 150, for example, a low-resistance silicon substrate and patterning the metal.

Referring to FIG. 5D, the substrate 102 is removed. In order to remove the substrate 102, the substrate 102 is primarily polished, and the substrate 102 may be completely removed by using an inductively coupled plasma/reactive ion etching (ICP RIE) method.

Referring to FIG. 5E, an upper surface of the buffer layer 105 may be corrugated by processing the upper surface of the buffer layer 105.

When a sapphire substrate is used as the substrate 102, the buffer layer 105 may not be formed.

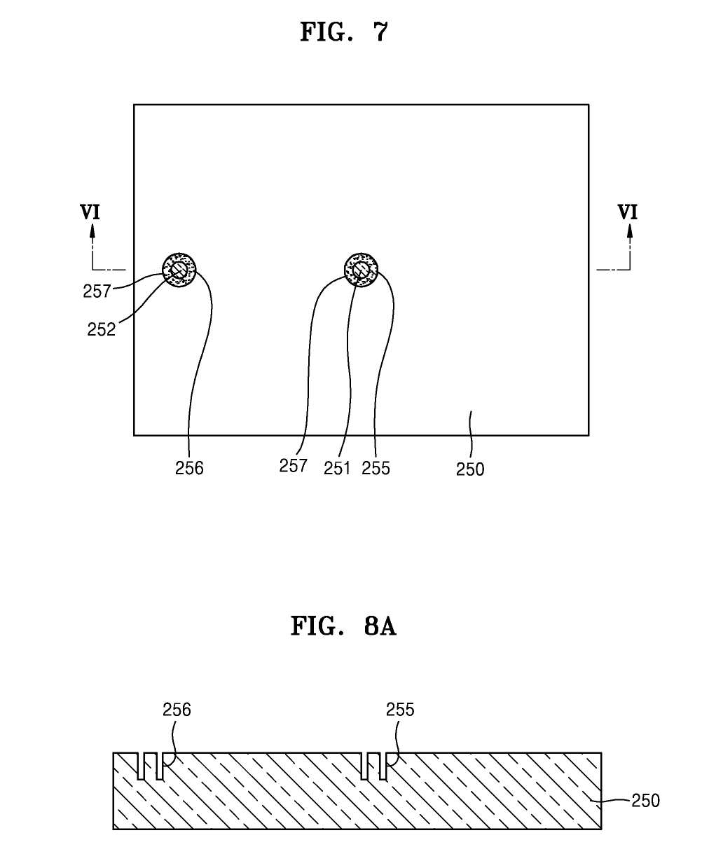

FIG. 6 is a schematic cross-sectional view of a structure of a vertical-type semiconductor light-emitting device 200 according to another example embodiment. FIG. 7 is a plan view taken along line VII-VII of FIG. 6. FIG. 6 is a cross-sectional view taken along the line VI-VI of FIG. 7. Like reference numerals are used to indicate elements that are substantially identical to the elements of the vertical-type semiconductor light-emitting device 100 of FIGS. 1 and 2, and the detailed descriptions thereof will not be repeated.

Referring to FIGS. 6 and 7, the vertical-type semiconductor light-emitting device 200 includes a semiconductor structure 110 and an electrode structure formed on one surface of the semiconductor structure 110. The semiconductor structure 110 may be substantially the same as the semiconductor structure 110 of FIG. 1.

A silicon substrate 250, for example, a low-resistance silicon substrate, is disposed on lower surfaces of the first bonding layer 141 and the second bonding layer 142. A first trench 255 and a second trench 256 that respectively correspond to the first bonding layer 141 and the second bonding layer 142 are formed in the silicon substrate 250, for example, low-resistance silicon substrate. In FIG. 7, the first and second trenches 255 and 256 have a circular shape. However, the shape of the first and second trenches 255 and 256 according to the current embodiment is not limited thereto. For example, the first and second trenches 255 and 256 may have a different shape, for example, a rectangular shape. The first and second trenches 255 and 256 are filled with a second insulating layer 257.

A first portion 251 and a second portion 252 that are formed of the same material as the silicon substrate 250, for example, low-resistance silicon substrate, are respectively filled inside the first and second trenches 255 and 256. The first portion 251 contacts the first bonding layer 141 and the second portion 252 contacts the second bonding layer 142. The second insulating layer 257 covers an upper surface of the silicon substrate 250, for example, the low-resistance silicon substrate, except the first portion 251 and the second portion 252.

Another conductive substrate may be used instead of the silicon substrate 250, for example, low-resistance silicon substrate. For example, the conductive substrate may be formed of a Ge group material, an Si group material that includes aluminum, a nitride group (GaN) material.

A first electrode pad 261 and a second electrode pad 262 may be formed on a lower surface of the silicon substrate 250, for example, low-resistance silicon substrate. The first electrode pad 261 is connected to the first portion 251, and the second electrode pad 262 is connected to the second portion 252.

In the vertical-type semiconductor light-emitting device 200 according to the current embodiment, since an area of the second insulating layer 257 that contacts the silicon substrate 250, for example, low-resistance silicon substrate, is greater than that of the second insulating layer 157 of the silicon substrate 150, for example, a low-resistance silicon substrate, strength of the silicon substrate 250 is increased.

A method of manufacturing the vertical-type semiconductor light-emitting device 200 according another example embodiment will be described with reference to drawings.

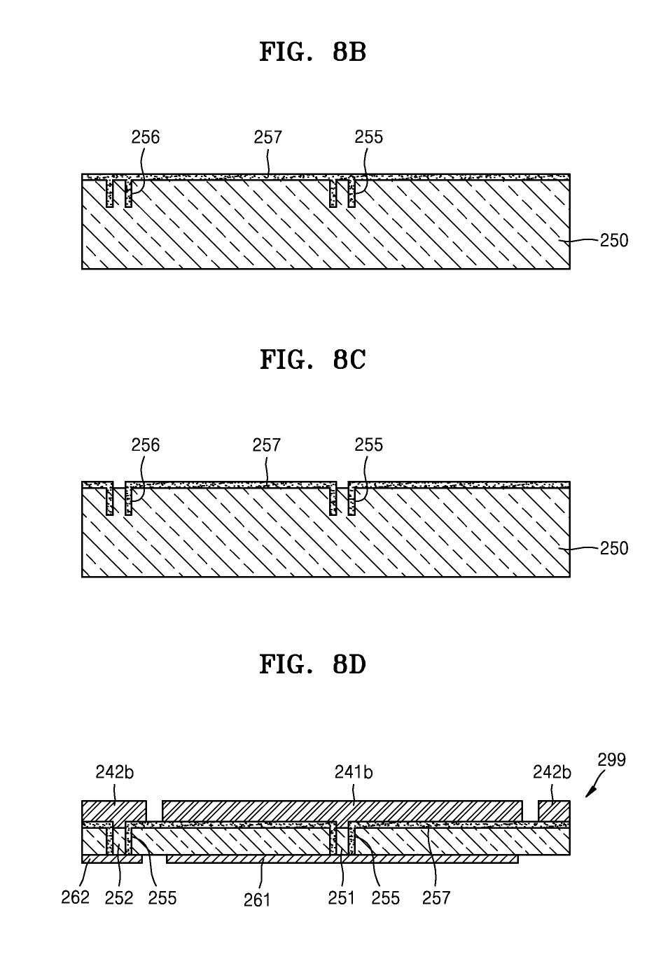

FIGS. 8A through 8D are cross-sectional views for explaining a method of preparing an electrode structure of the vertical-type semiconductor light-emitting device 200 of FIG. 6.

Referring to FIG. 8A, a conductive substrate 250 is prepared. The conductive substrate 250 may be a low-resistance silicon substrate. However, the conductive substrate 250 according to the example embodiment is not limited thereto. For example, the conductive substrate 250 may be formed of a Ge group material, a Si group material that includes aluminum, or a nitride group material (GaN etc.). Hereinafter, a method of manufacturing an electrode structure with a silicon substrate 250 will be described.

First and second trenches 255 and 256 are formed on an upper surface of the silicon substrate 250, for example, the low-resistance silicon substrate. The first trench 255 is formed on a region corresponding to the first bonding layer 141 and the second trench 256 is formed on a region corresponding to the second bonding layer 142. The first and second trenches 255 and 256 respectively may be formed in a circular shape or a rectangular shape. The first and second trenches 255 and 256 respectively may have a depth in a range from about 100 μm to about 300 μm and a diameter in a range from about 1 μm to about 10 μm.

Referring to FIG. 8B, a second insulating layer 257 that fills the first and second trenches 255 and 256 is formed on the upper surface of the silicon substrate 250, for example, low-resistance silicon substrate. The second insulating layer 257 may be formed of an oxide, a nitride, or a polymer. The second insulating layer 257 may be a silicon oxide layer that is formed by thermally oxidizing the silicon substrate 250, for example, low-resistance silicon substrate. In order for the silicon oxide layer to be completely filled in the first and second trenches 255 and 256, the first and second trenches 255 and 256 may have a depth in a range from about 100 μm to about 300 μm and a diameter in a range from about 1 μm to about 10 μm.

Referring to FIG. 8C, the second insulating layer 257 that is surrounded by the first trench 255 and the second insulating layer 257 that is surrounded by the second trench 256 are removed from the upper surface of the silicon substrate 250, for example, low-resistance silicon substrate.

Referring to FIG. 8D, a third bonding layer 241b and a fourth bonding layer 242b are formed to correspond to the first bonding layer 141a and the second bonding layer 142a. The third bonding layer 241b and the fourth bonding layer 242b may be formed of an eutectic bonding material, for example, AuSn, NiSn, CuSn, AgSn, etc. The resultant structure of FIG. 8D is referred to as an electrode structure 299.

A process of bonding the semiconductor structure 110 and the electrode structure 299 is appreciated with reference to FIGS. 5A through 5E and a description thereof, and thus, the description thereof will not be repeated.

As described above, in a vertical-type semiconductor light-emitting device according to the example embodiments, electrodes that are connected to semiconductor layers are formed on a lower surface of the vertical-type semiconductor light-emitting device, and thus, the electrodes are formed so as not to reduce the light-emitting area. Therefore, the light-emitting efficiency may be increased.

Also, a current supply region for supplying current to a conductive layer is confined by trenches without using a TSV substrate, and thus, the manufacturing cost may be reduced.

While one or more example embodiments have been described with reference to the figures, it will be understood by those of ordinary skill in the art that various changes in form and details may be made therein without departing from the spirit and scope as defined by the following claims.

1. A semiconductor light-emitting device comprising:
an active layer and a first semiconductor layer sequentially stacked on a second semiconductor layer, the active layer and the second semiconductor layer including a plurality of contact holes exposing portions of the first semiconductor layer in a first region of the second semiconductor layer;
a plurality of first electrodes on respective ones of the exposed portions of the first semiconductor layer;
a second electrode on the second semiconductor layer, the second electrode adjacent to the plurality of contact holes;
a first insulating layer on the second electrode in the first region extending to cover the plurality of contact holes to expose the plurality of first electrodes, the first insulating layer configured to insulate the plurality of first electrodes from the active layer and the second semiconductor layer;
a first bonding layer on the first insulating layer and filling the plurality of contact holes, the first bonding layer connected to the plurality of first electrodes;
a second bonding layer on the second electrode; and
a conductive layer including a first portion contacting a lower surface of the first bonding layer and a second portion contacting a lower surface of the second bonding layer, the second portion of the conductive layer surrounding the first portion of the conductive layer.

2. The semiconductor light-emitting device of claim 1, further comprising:
a buffer layer on the first semiconductor layer, the buffer layer having a corrugated surface.

3. (canceled)

4. The semiconductor light-emitting device of claim 1, wherein the second electrode is a reflective layer configured to reflect light emitted from the active layer.

5. The semiconductor light-emitting device of claim 1, wherein the first and second bonding layers include one of AuSn, NiSn, CuSn and AgSn.

6. The semiconductor light-emitting device of claim 1, further comprising:
a second insulating layer disposed in a trench between the first portion and the second portion of the conductive layer, the second insulating layer surrounds the first portion of the conductive layer.

7. The semiconductor light-emitting device of claim 6, wherein the trench has a width in a range from about 1 μm about 10 μm.

8. The semiconductor light-emitting device of claim 1, wherein the conductive layer is a silicon substrate.

9. The semiconductor light-emitting device of claim 1, further comprising:
a first electrode pad connected to a lower surface of the first portion; and
a second electrode pad connected to a lower surface of the second portion.

10-17. (canceled)
